(19) United States
(12) Patent Application Publication
(10) Pub. No.: US 2023/0144512 A1
(43) Pub. Date: May 11, 2023

(54) RESISTIVE SWITCHING MEMORY, RESISTIVE SWITCHING ELEMENT AND MANUFACTURING METHOD FOR THE SAME

(71) Applicant: XIAMEN INDUSTRIAL TECHNOLOGY RESEARCH INSTITUE CO.,LTD., Xiamen (CN)

(72) Inventors: Yu LIU, Xiamen (CN); Tingying SHEN, Xiamen (US); SZU-CHUN KANG, Xiamen (CN); Taiwei CHIU, Xiamen (CN); Danyun WANG, Xiamen (CN); Lijun SHAN, Xiamen (CN)

(21) Appl. No.: 18/052,921

(22) Filed: Nov. 6, 2022

Related U.S. Application Data
(63) Continuation of application No. PCT/CN2021/096423, filed on May 27, 2021.

(30) Foreign Application Priority Data
Sep. 1, 2020 (CN) 202010904835.5

(51) Int. Cl. H10N 70/00; H10B 63/00; H10N 70/20

(52) U.S. Cl. CPC H10N 70/828; H10B 63/80; H10N 70/24; H10N 70/063

(57) ABSTRACT

The present disclosure discloses a method for manufacturing a resistive switching element, including: performing an etching process, a deposition process and a polishing process alternately to prepare the bottom electrode, the resistive switching layer and the top electrode; and optimizing at least one of the bottom electrode, the resistive switching materials and the oxygen storage layer by using the sidewall process when preparing the bottom electrode and the resistive switching materials, so as to reduce a contact area between the bottom electrode and the resistive switching materials, and/or reduce a contact area between the resistive switching materials and the oxygen storage layer. The method could form conductive filaments in the resistive switching layer, and a low resistive state and high resistive state are realized by forming and breaking conductive filaments. The present disclosure further discloses a resistive switching element and a resistive switching memory having the resistive switching element.

### TECHNICAL FIELD

The present disclosure is a continuation application of International Application No. PCT/CN2021/096423, filed on May 27, 2021, which claims priority of Chinese Patent Application No. 202010904835.5, filed Sep. 1, 2020, in CNIPA (China National Intellectual Property Administration), the disclosures of all of which are hereby incorporated by reference.

### TECHNICAL FIELD

The present disclosure relates to the field of storage technology, in particular, to a method for manufacturing a resistive switching element, a resistive switching element and a resistive switching memory having the same.

### BACKGROUND

In the related art, the resistive switching element is consisted of bottom electrodes, a resistive switching layer and top electrodes, and the resistive switching layer is located between the top electrodes and the bottom electrodes. Generally, a Conductive filament can be formed in the resistive switching layer by applying a voltage to the resistive switching element. Thereby, a low resistance state and a high resistance state are realized by the formation and breakage of the conductive filaments.

However, in the existing resistive switching element, the contact area between elements is relatively large, and thus the conductive filaments are distributed very randomly on the contact surface, thereby affecting the electrical performance of the entire resistive switching element.

### SUMMARY

The present invention aims to solve one of the technical problems as described above at least to a certain extent. To this end, an object of the present invention is to provide a method for manufacturing a resistive switching element, so that the conductive filaments are gathered in a small effective area, and the electrical properties of the resistive switching element can be greatly improved.

Another object of the present invention is to provide a resistive switching element.

Yet another object of the present invention is to provide a resistive switching memory.

In order to achieve the above objects, an embodiment according to a first aspect of the present invention provides a method for manufacturing a resistive switching element, wherein the resistive switching element includes a bottom electrode, a top electrode and a resistive switching layer disposed between the bottom electrode and the top electrode, the resistive switching layer includes an oxygen storage layer adjacent to the top electrode and resistive switching materials adjacent to the bottom electrode, and the method includes steps of: performing an etching process, a deposition process and a polishing process alternately to prepare the bottom electrode, the resistive switching layer and the top electrode; optimizing at least one of the bottom electrode, the resistive switching materials and the oxygen storage layer by using the sidewall process when preparing the bottom electrode and the resistive switching materials, so as to reduce a contact area between the bottom electrode and the resistive switching materials, and/or reduce a contact area between the resistive switching materials and the oxygen storage layer.

The method for manufacturing a resistive switching element according to the present invention is provided, where the resistive switching element includes a bottom electrode, a top electrode and a resistive switching layer disposed between the bottom electrode and the top electrode, the resistive switching layer includes an oxygen storage layer adjacent to the top electrode and resistive switching materials adjacent to the bottom electrode, the method includes steps of: performing an etching process, a deposition process and a polishing process alternately to prepare the bottom electrode, the resistive switching layer and the top electrode; optimizing at least one of the bottom electrode, the resistive switching materials and the oxygen storage layer by using the sidewall process when preparing the bottom electrode and the resistive switching materials, so as to reduce a contact area between the bottom electrode and the resistive switching materials, and/or reduce a contact area between the resistive switching materials and the oxygen storage layer, by using optimization process. Therefore, the contacting area between components of the resistive switching element is reduced, conductive filaments are gathered in a small effective area, and thus the electrical properties of the resistive switching element can be greatly improved.

In addition, the method for manufacturing a resistive switching element according to the present invention further includes the following additional features.

Alternatively, according to an embodiment of the present invention, optimizing the resistive switching materials by using the sidewall process includes depositing a first protective dielectric layer on the prepared bottom electrode, and etching the first protective dielectric layer to form a trench above the bottom electrode, wherein the trench covers part of the bottom electrode; and successively depositing resistive switching materials and a second protective dielectric layer on the first protective dielectric layer with the trench, and polishing the second protective dielectric layer.

Alternatively, according to an embodiment of the present invention, optimizing the resistive switching materials by using the sidewall process includes depositing a first protective dielectric layer on the prepared bottom electrode, and etching the first protective dielectric layer to form a protective dielectric block above the bottom electrode, wherein the protective dielectric block covers part of the bottom electrode; and successively depositing resistive switching materials and a second protective dielectric layer on the bottom electrode with the protective dielectric block, and polishing the second protective dielectric layer.

Alternatively, according to an embodiment of the present invention, the method further includes the following steps after polishing the second protective dielectric layer: successively depositing the oxygen storage layer and a top electrode layer above the polished second protective dielectric layer, and etching the deposited oxygen storage layer and top electrode layer to form an oxygen storage layer and a top electrode above and corresponding to the bottom electrode; depositing ultra-low K materials, and polishing and etching the etched ultra-low K materials to form a channel corresponding to a position of the top electrode; and depositing interconnection metal in the channel and polishing the deposited interconnection metal.

Alternatively, according to an embodiment of the present invention, optimizing the oxygen storage layer by using the sidewall process includes successively depositing resistive switching materials and a sidewall dielectric layer on the prepared bottom electrode, and etching the sidewall dielectric layer to form a sidewall dielectric layer block, wherein the sidewall dielectric layer block covers the resistive switching materials above and corresponding to part of the bottom electrode; depositing the oxygen storage layer on the etched sidewall dielectric layer, and etching the oxygen storage layer to retain an oxygen storage block on at least one of two sides of the sidewall dielectric layer block, wherein the oxygen storage block is located above the bottom electrode; depositing ultra-low K materials on the sidewall dielectric layer block with the oxygen storage block, and polishing and etching the deposited ultra-low K materials to form a first channel on the sidewall dielectric layer block, wherein the first channel is staggered from bottom electrode; depositing ultra-low K materials in the first channel, and polishing and etching the deposited ultra-low K materials to form a second channel above the oxygen storage block; and depositing the top electrode in the second channel and polishing the deposited top electrode.

Alternatively, according to an embodiment of the present invention, optimizing the oxygen storage layer by using the sidewall process includes successively depositing resistive switching materials and a sidewall dielectric layer on the prepared bottom electrode, and etching the sidewall dielectric layer to form a sidewall dielectric layer block, wherein the sidewall dielectric layer block covers the resistive switching materials above and corresponding to part of the bottom electrode; depositing the oxygen storage layer on the etched sidewall dielectric layer, and etching the oxygen storage layer to retain an oxygen storage block on at least one of two sides of the sidewall dielectric layer block, wherein the oxygen storage block is located above the bottom electrode; depositing ultra-low K materials on the sidewall dielectric layer block with the oxygen storage block, and polishing and etching the deposited ultra-low K materials to form a channel on the oxygen storage block; and depositing the top electrode in the channel and polishing the deposited top electrode.

Alternatively, according to an embodiment of the present invention, optimizing the oxygen storage layer by using the sidewall process includes depositing a sidewall dielectric layer on the prepared bottom electrode, and etching the sidewall dielectric layer to form a sidewall dielectric layer block, wherein the sidewall dielectric layer block covers part of the bottom electrode; depositing the oxygen storage layer on the etched sidewall dielectric layer, and etching the oxygen storage layer to retain an oxygen storage block on at least one of two sides of the sidewall dielectric layer block, wherein the oxygen storage block is located above the bottom electrode; depositing ultra-low K materials on the sidewall dielectric layer block with the oxygen storage block and polishing the deposited ultra-low K materials, and depositing the resistive switching materials and a top electrode layer; and etching the top electrode layer to form the top electrode on the oxygen storage block.

Alternatively, according to an embodiment of the present invention, optimizing the bottom electrode by using the sidewall process includes: depositing a sidewall dielectric layer on a substrate of ultra-low K materials with a through hole, and etching the sidewall dielectric layer to form a sidewall dielectric layer block, wherein the sidewall dielectric layer block covers part of the through hole; and depositing a bottom electrode layer on the etched sidewall dielectric layer, and etching the bottom electrode layer to retain a bottom electrode on at least one of two sides of the sidewall dielectric layer block, wherein the bottom electrode is located above the through hole.

Alternatively, according to an embodiment of the present invention, after the bottom electrode is prepared, the method further comprises: depositing ultra-low K materials on the sidewall dielectric layer block with the bottom electrode, polishing and etching the deposited ultra-low K materials to form a first channel on the sidewall dielectric layer block, wherein the first channel is staggered from the location of the through hole; depositing ultra-low K materials in the first channel and polishing the deposited ultra-low K materials, and then depositing the resistive switching materials, the oxygen storage layer and a top electrode layer successively; etching the oxygen storage layer and the top electrode layer to form an oxygen storage block and the top electrode above the bottom electrode; depositing ultra-low K materials on the etched oxygen storage layer and top electrode layer, and polishing and etching the deposited ultra-low K materials to form a second channel above the top electrode; and depositing interconnection metal in the second channel and polishing the deposited interconnection metal.

Alternatively, according to an embodiment of the present invention, after the bottom electrode is prepared, the method further includes: depositing ultra-low K materials on the sidewall dielectric layer block with the bottom electrode, and polishing the deposited ultra-low K materials; successively depositing the resistive switching materials, the oxygen storage layer and a top electrode layer; etching the oxygen storage layer and the top electrode layer to form an oxygen storage blocks and a top electrode above the bottom electrode; depositing ultra-low K materials on the etched oxygen storage layer and top electrode layer, and polishing and etching he deposited ultra-low K materials to form a channel above the top electrode; and depositing interconnection metal in the channel and polishing the deposited interconnection metal.

In order to achieve the above objects, an embodiment according to another aspect of the present invention provides a resistive switching element manufactured according to the method as described above.

In the resistive switching element according to the embodiments of the present invention, the contacting area between components of the resistive switching element is reduced, conductive filaments are gathered in a small effective area, and thus the electrical properties of the resistive switching element can be greatly improved.

In order to achieve the above objects, an embodiment according to yet another aspect of the present invention provides a resistive switching memory including a plurality of resistive switching elements as described above, and the plurality of resistive switching elements are arranged in an array.

In the resistive switching memory according to the embodiments of the present invention, the contacting area between components of the resistive switching elements in the resistive switching memory is reduced, conductive filaments are gathered in a small effective area, and thus the electrical properties of the resistive switching element can be greatly improved. Besides, the resistive switching elements in are arranged in an array, which greatly improving the electric properties of the entire resistive switching memory.

### BRIEF DESCRIPTION OF THE DRAWINGS

FIG. 1 is a schematic flowchart illustrating a method for manufacturing a resistive switching element according to an embodiment of the present invention;

FIG. 2 is a schematic flowchart illustrating a method for manufacturing a resistive switching element according to another embodiment of the present invention;

FIGS. 3A-3K illustrate a process for manufacturing the resistive switching element which corresponds to the method for manufacturing the resistive switching element illustrated in FIG. 2;

FIG. 4 is a schematic flowchart illustrating a method for manufacturing a resistive switching element according to yet another embodiment of the present invention;

FIGS. 5A-5K illustrate a process for manufacturing the resistive switching element which corresponds to the method for manufacturing the resistive switching element illustrated in FIG. 4;

FIG. 6 is a schematic diagram illustrating a process flow for optimizing an oxygen storage layer according to an embodiment of the present invention;

FIGS. 7A-7I illustrate a manufacturing process corresponding to the processing flow illustrated in FIG. 6;

FIG. 8 is a schematic diagram illustrating a process flow for optimizing an oxygen storage layer according to another embodiment of the present invention;

FIGS. 9A-9G illustrate a manufacturing process corresponding to the processing flow illustrated in FIG. 8;

FIG. 10 is a schematic diagram illustrating a process flow for optimizing an oxygen storage layer according to yet another embodiment of the present invention;

FIGS. 11A-11H illustrate a manufacturing process corresponding to the processing flow illustrated in FIG. 10;

FIG. 12 is a schematic flowchart illustrating a method for manufacturing a resistive switching element according to a specific embodiment of the present invention;

FIGS. 13A-13N illustrate a process for manufacturing a resistive switching element which corresponds to the method for manufacturing the resistive switching element illustrated in FIG. 12;

FIG. 14 is a schematic flowchart illustrating a method for manufacturing a resistive switching element according to another specific embodiment of the present invention;

FIGS. 15A-15L illustrate a process for manufacturing a resistive switching element which corresponds to the method for manufacturing the resistive switching element illustrated in FIG. 14.

### DETAILED DESCRIPTION

Details of the embodiments of the present invention will be described in the following, and examples of the embodiments are illustrated with reference to the accompanying drawings, wherein the same or similar reference numerals refer to the same or similar elements or elements having the same or similar functions throughout the description. The embodiments described below with reference to the accompanying drawings are exemplary and are intended to explain the present invention, which should not be construed as limiting the present invention.

In the related art, in the resistive switching element, the contact area between the components is large, and thus the conductive filaments are distributed very randomly on the contact surface, thereby affecting the electrical properties of the entire resistive switching element. According to the method for manufacturing the resistive switching element, the resistive switching element includes a bottom electrode, a top electrode and a resistive switching layer disposed between the bottom electrode and the top electrode, where the resistive switching layer includes an oxygen storage layer adjacent to the top electrode and resistive switching materials adjacent to the bottom electrode. The method includes: firstly, performing an etching process, a deposition process and a polishing process alternately to prepare the bottom electrode, the resistive switching layer and the top electrode. In the process of preparing the bottom electrode and the resistive switching layer, a sidewall process is used to optimize at least one of the bottom electrode, the resistive switching materials and the oxygen storage layer, so as to reduce a contact area between the bottom electrode and the resistive switching materials, and/or reduce a contact area between the resistive switching materials and the oxygen storage layer. Thus, the contact area between components in the resistive switching element is reduced, the conductive filaments are gathered in a small effective area, and the electrical properties of the resistive switching element can be greatly improved.

For better understanding of the above technical solutions, exemplary embodiments of the present invention will be described in more detail below with reference to the accompanying drawings. While exemplary embodiments of the present invention are shown in the drawings, it should be understood that the present invention may be embodied in various forms and should not be limited by the embodiments set forth herein. Rather, these embodiments are provided so that the present invention will be more thoroughly understood, and the scope of the invention will be fully conveyed to those skilled in the art.

In order to better understand the above technical solutions, the above technical solutions will be described in detail below with reference to the accompanying drawings and specific embodiments.

The method for manufacturing the resistive switching element, the resistive switching element and the resistive switching memory according to the embodiments of the present invention will be described below with reference to the accompanying drawings.

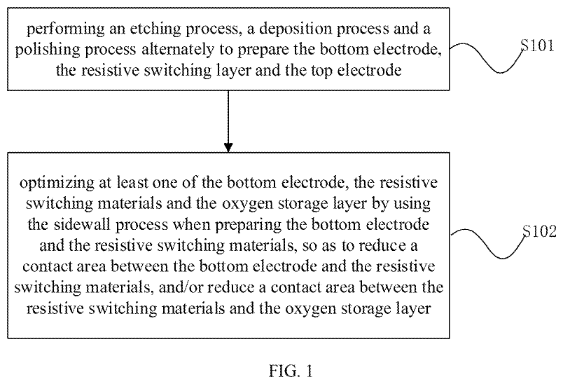

FIG. 1 is a schematic flowchart illustrating a method for manufacturing a resistive switching element according to an embodiment of the present invention, where the resistive switching element comprises a bottom electrode, a top electrode and a resistive switching layer disposed between the bottom electrode and the top electrode, and the resistive switching layer includes an oxygen storage layer adjacent to the top electrode and resistive switching materials adjacent to the bottom electrode.

As shown in FIG. 1, the method for manufacturing the resistive switching element includes the following steps:

At S101, an etching process, a deposition process, and a polishing process are performed alternately to prepare a bottom electrode, a resistive switching layer and a top electrode.

At S102, in the process of preparing the bottom electrode and the resistive switching layer, a sidewall process is used to optimize at least one of the bottom electrode, the resistive switching materials and the oxygen storage layer, so that the contact area between the bottom electrode and the resistive switching materials are reduced, and/or the contact area between the resistive switching materials and the oxygen storage layer is reduced.

That is to say, the etching process, the deposition process and the polishing process are performed alternately to prepare the bottom electrode, the resistive switching layer and the top electrode; and, in the process of preparing the bottom electrode and the resistive switching layer, the sidewall process is used for optimizing at least one of the bottom electrode , the resistive switching materials and the oxygen storage layer, so that the contact area between the bottom electrode and the resistive switching materials are reduced; or the contact area between the resistive switching materials and the oxygen storage layer is reduced. Or, the contact area between the bottom electrode and the resistive switching materials and the area between the resistive switching materials and the oxygen storage layer is reduced, so that the conductive filaments are gathered in a smaller effective area, which greatly improves the electrical properties of the resistive switching element.

There are many ways to optimize the resistive switching materials by using the sidewall process.

In some embodiments, optimizing the resistive switching materials by using the sidewall process includes: depositing a first protective dielectric layer on the prepared bottom electrode, and etching the first protective dielectric layer to form a trench above the bottom electrode, where the trench covers part of the bottom electrode; and successively depositing resistive switching materials and a second protective dielectric layer on the first protective dielectric layer with the trench, and polishing the second protective dielectric layer.

In some embodiment optimizing the resistive switching materials by using the sidewall process includes: depositing a first protective dielectric layer on the prepared bottom electrode, and etching the first protective dielectric layer to form a protective dielectric block above the bottom electrode, where the protective dielectric block covers part of the bottom electrode; and successively depositing resistive switching materials and a second protective dielectric layer on the bottom electrode with the protective dielectric block, and polishing the second protective dielectric layer.

In some embodiments, after polishing the second protective dielectric layer, the method further includes: successively depositing the oxygen storage layer and a top electrode layer above the polished second protective dielectric layer, and etching the deposited oxygen storage layer and top electrode layer to form an oxygen storage layer and a top electrode above and corresponding to the bottom electrode; depositing ultra-low K materials, and polishing and etching the etched ultra-low K materials to form a channel corresponding to a position of the top electrode; and depositing interconnection metal in the channel and polishing the deposited interconnection metal.

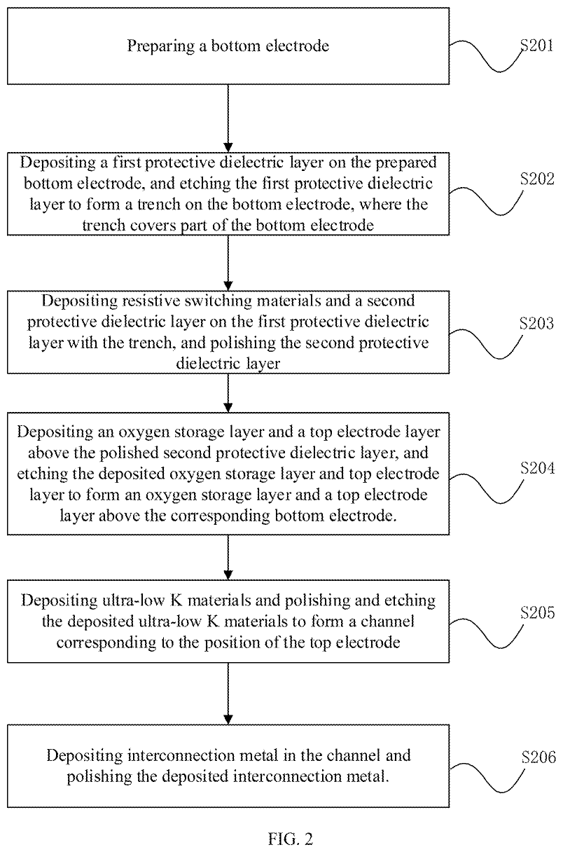

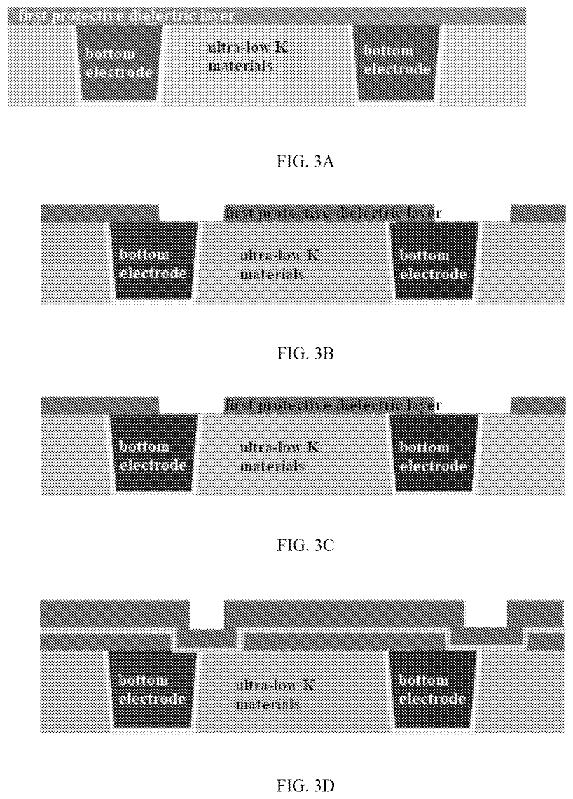

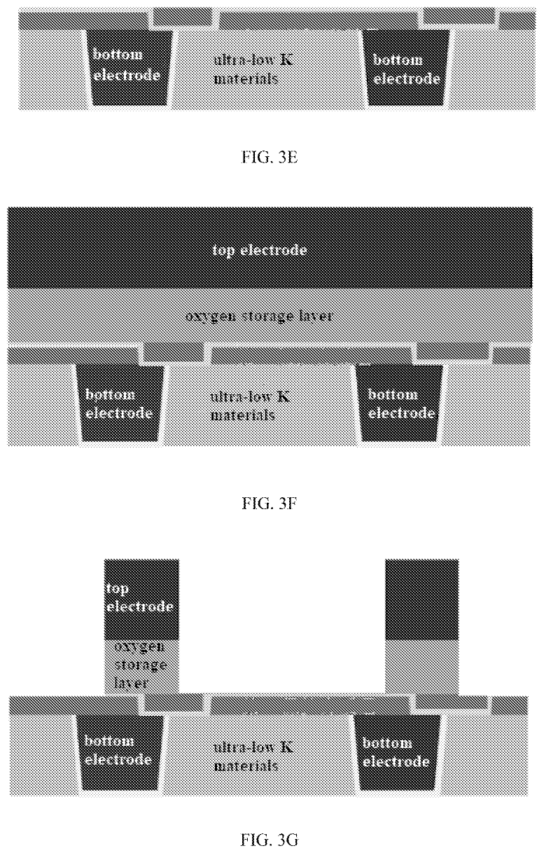

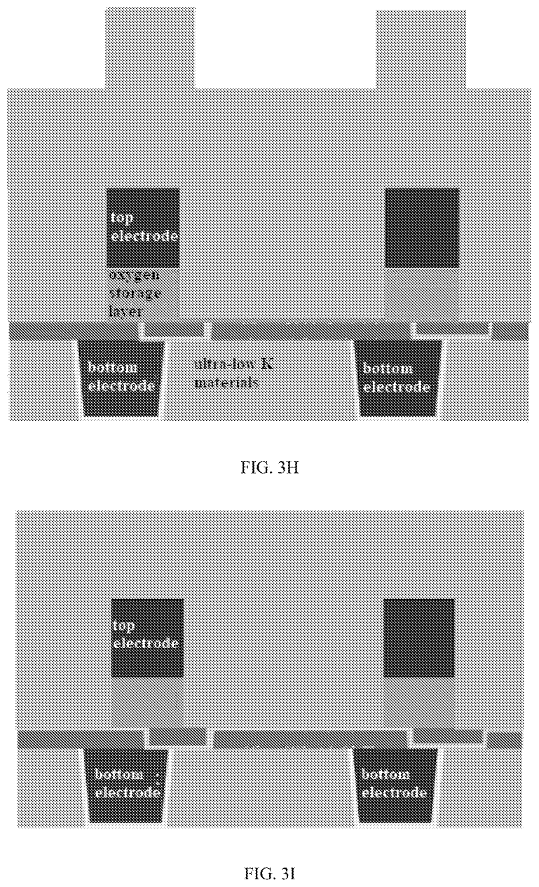

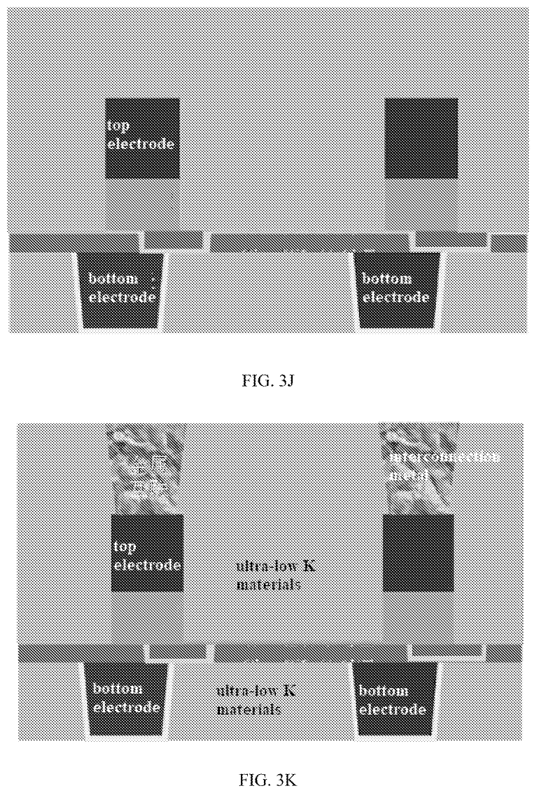

FIG. 2 and FIGS. 3A-3K illustrate an example of the present invention. FIG. 2 is a schematic flowchart illustrating a method for manufacturing a resistive switching element according to a specific embodiment of the present invention, and FIGS. 3A-3K illustrate result corresponding to the method for manufacturing the resistive switching element. As shown in FIG. 2, the method for manufacturing the resistive switching element includes the following steps:

At S201, the bottom electrode is prepared.

At S202, a first protective dielectric layer is deposited on the prepared bottom electrode, and the first protective dielectric layer is etched to form a trench on the bottom electrode, where the trench covers part of the bottom electrode.

That is, after the bottom electrode is prepared, as shown in FIG. 3A, firstly, a first protective dielectric layer is deposited on the prepared bottom electrode through a deposition process; then, as shown in FIG. 3B, an etching process is used to etch the first protective dielectric layer to form a trench above the bottom electrode, and the trench covers part of the bottom electrode, thus, the contact area of the bottom electrode can be reduced in this way.

At S203, resistive switching materials and a second protective dielectric layer are successively deposited on the first protective dielectric layer with the trench, and the second protective dielectric layer is polished.

That is, as shown in FIG. 3C, firstly, resistive switching materials are deposited on the first protective dielectric layer with the trench; then, as shown in FIG. 3D, a second protective dielectric layer is deposited, and the second protective dielectric layer is polished to obtain the element as shown in FIG. 3E.

It should be noted that by depositing the first protective dielectric layer, the resistive switching materials and the second protective dielectric layer through the deposition process, the process induced damage to the intermediate dielectric layer will be avoided (it can be understood that if the size of the resistive switching element is defined by the etching process, the edge of the resistive switching element will inevitably be damaged by the etching process, so that the conductive filaments are easily distributed at the edge of the resistive switching element, and thus is easily affected by external factors, thereby the high and low resistance state distribution of the resistive switching element will be dispersed), and thus the electrical properties of resistive switching element is improved.

At S204, an oxygen storage layer and a top electrode layer are successively deposited above the polished second protective dielectric layer, and the deposited oxygen storage layer and top electrode layer are etched to form an oxygen storage layer and a top electrode layer above the corresponding bottom electrode.

At S205, ultra-low K materials are deposited and polishing and etching are performed to form a channel corresponding to the position of the top electrode.

At S206, interconnection metal is deposited in the channel and then polished.

That is, as shown in FIG. 3F, an oxygen storage layer and a top electrode layer are successively deposited above the polished second protective dielectric layer; then, the deposited oxygen storage layer and top electrode layer are etched through an etching process, so that an oxygen storage layer and a top electrode are formed above the corresponding bottom electrode, and thereby obtaining the element shown in FIG. 3G; then, as shown in FIGS. 3H to 3J, the ultra-low K materials are deposited through a deposition process, and the deposited ultra-low K materials are polished and etched to form the channel corresponding to the position of the top electrode; then, as shown in FIG. 3K, interconnection metal is deposited on the channel and then polished to complete the manufacture of the resistive switching element.

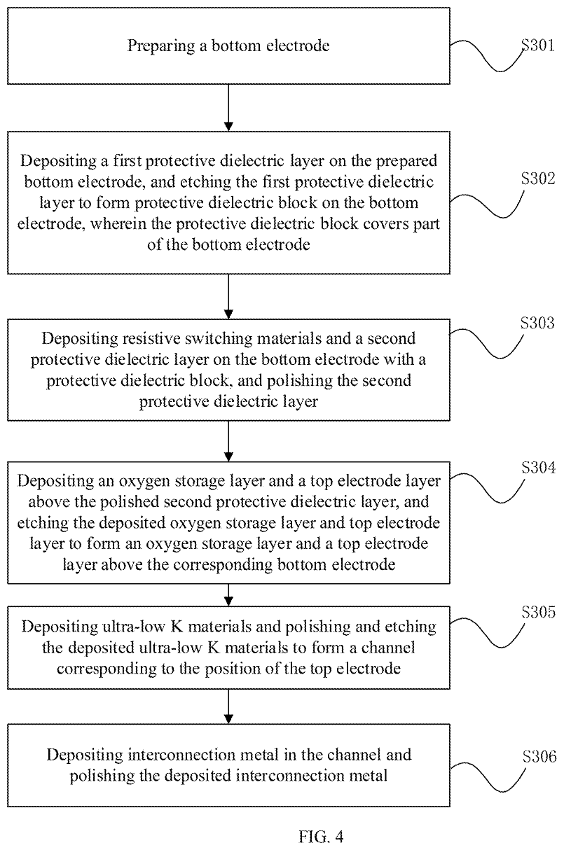

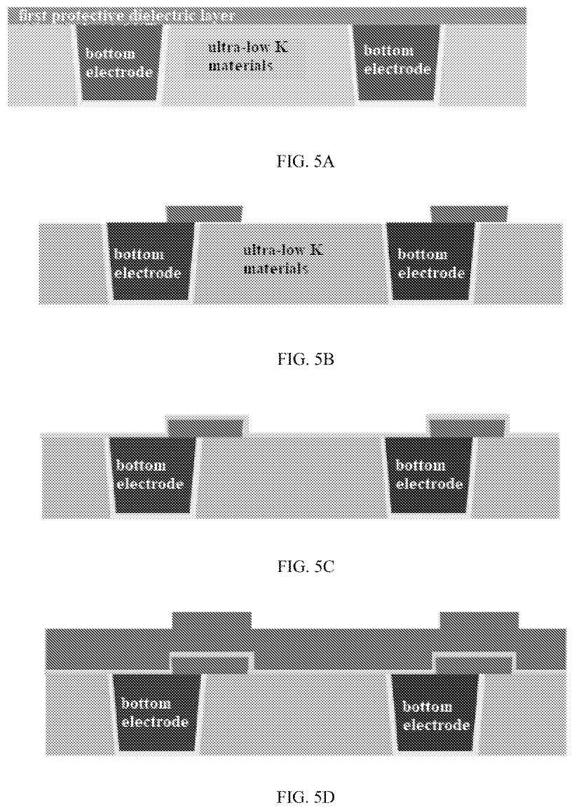

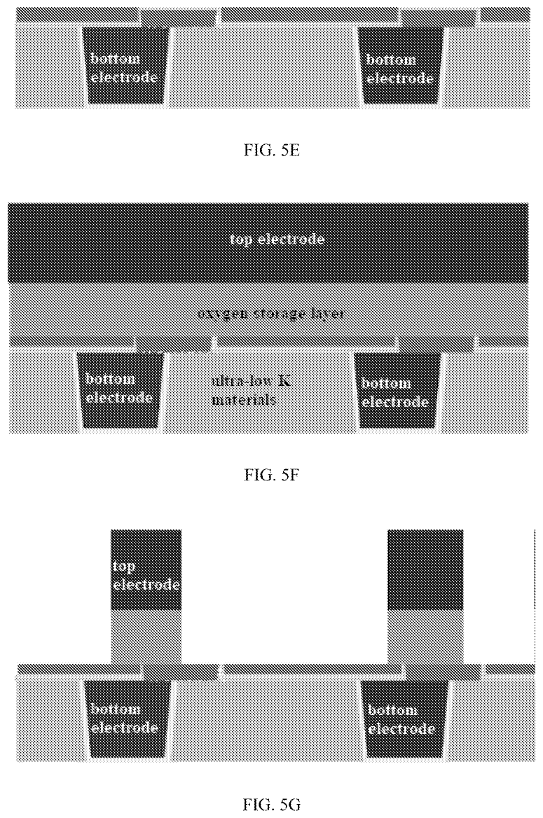

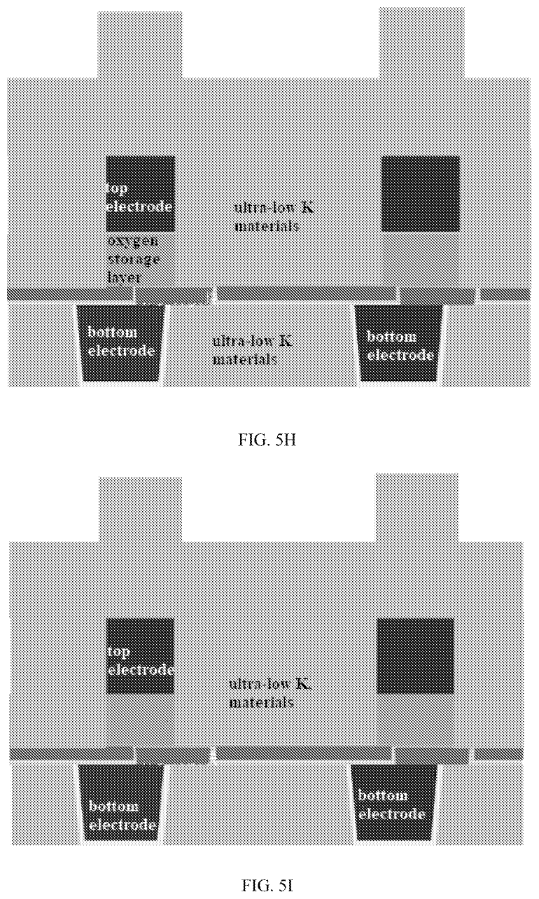

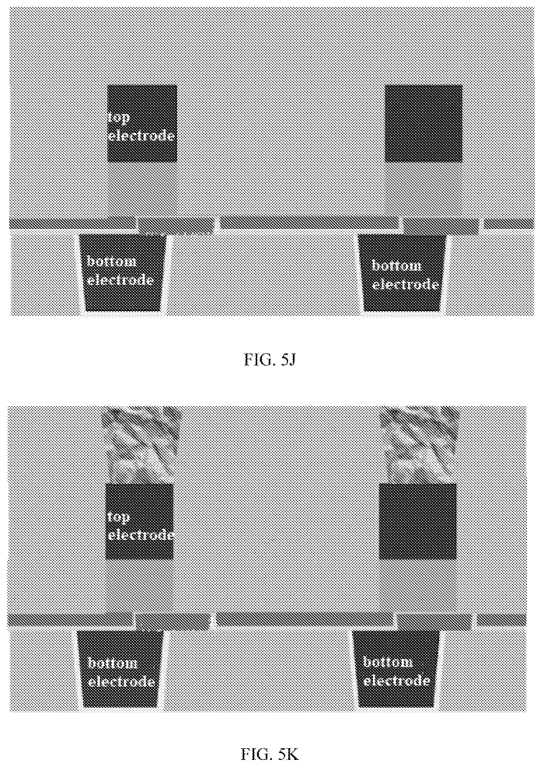

FIG. 4 and FIGS. 5A-5K illustrate another example of the present invention. FIG. 2 is a schematic flowchart illustrating a method for manufacturing a resistive switching element according to another specific embodiment of the present invention, and FIGS. 5A-5K illustrate results corresponding to the method for manufacturing the resistive switching element. As shown in FIG. 4, the method for manufacturing the resistive switching element includes the following steps:

At S301, the bottom electrode is prepared.

At S302, a first protective dielectric layer is deposited on the prepared bottom electrode, and the first protective dielectric layer is etched to form a protective dielectric block on the bottom electrode, wherein the protective dielectric block covers part of the bottom electrode.

That is, after the bottom electrode is prepared, as shown in FIG. 5A, firstly, a first protective dielectric layer is deposited on the prepared bottom electrode; then, as shown in FIG. 5B, the first protective dielectric layer is etched to form a protective dielectric block above the bottom electrode, and the protective dielectric block covers part of the bottom electrode.

At S303, resistive switching materials and a second protective dielectric layer are successively deposited on the bottom electrode with a protective dielectric block, and then the second protective dielectric layer is polished.

That is, as shown in FIG. 5C, firstly, resistive switching materials are deposited on the bottom electrode with a protective dielectric block; then, as shown in FIG. 5D, a second protective dielectric layer is deposited and then the second protective dielectric layer is polished to obtain the element as shown in FIG. 5E.

At S304, an oxygen storage layer and a top electrode layer are deposited successively above the polished second protective dielectric layer, and the deposited oxygen storage layer and top electrode layer are etched to form an oxygen storage layer and a top electrode layer above the corresponding bottom electrode.

At S305, ultra-low K materials are deposited, polished and etched to form a channel corresponding to the position of the top electrode.

At S306, interconnection metal is deposited in the channel and polished.

That is, as shown in FIG. 5F, an oxygen storage layer and a top electrode layer are successively deposited above the polished second protective dielectric layer; then, the deposited oxygen storage layer and top electrode layer are etched through an etching process, so that an oxygen storage layer and a top electrode are formed above the corresponding bottom electrode, and thereby obtaining the element shown in FIG. 5G; then, as shown in FIGS. 5H to 5J, the ultra-low K materials are deposited through a deposition process, and the deposited ultra-low K materials are polished and etched to form the channel corresponding to the position of the top electrode; then, as shown in FIG. 5K, interconnection metal is deposited in the channel and then polished to complete the preparation of the resistive switching element.

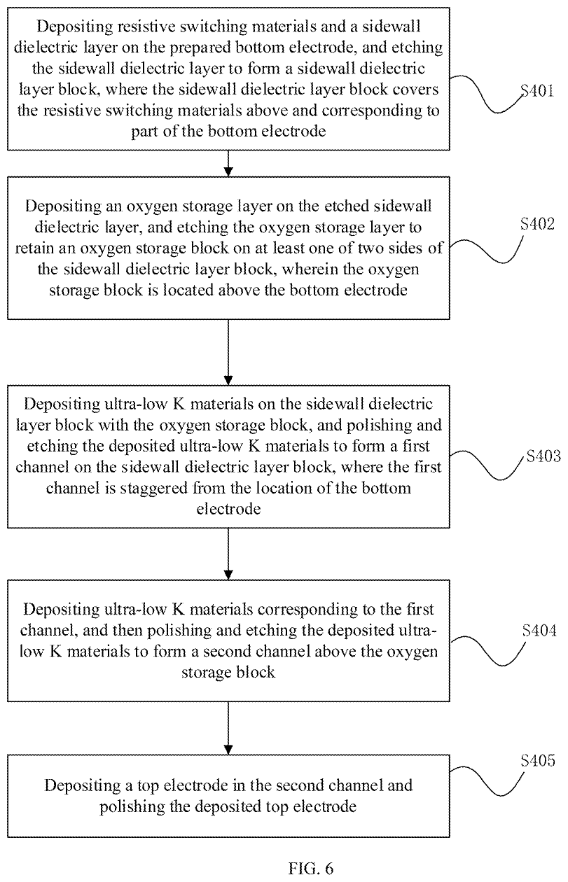

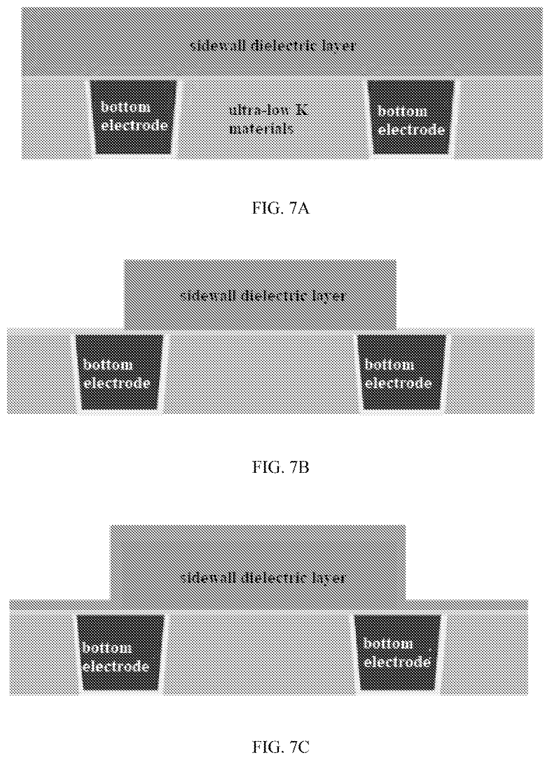

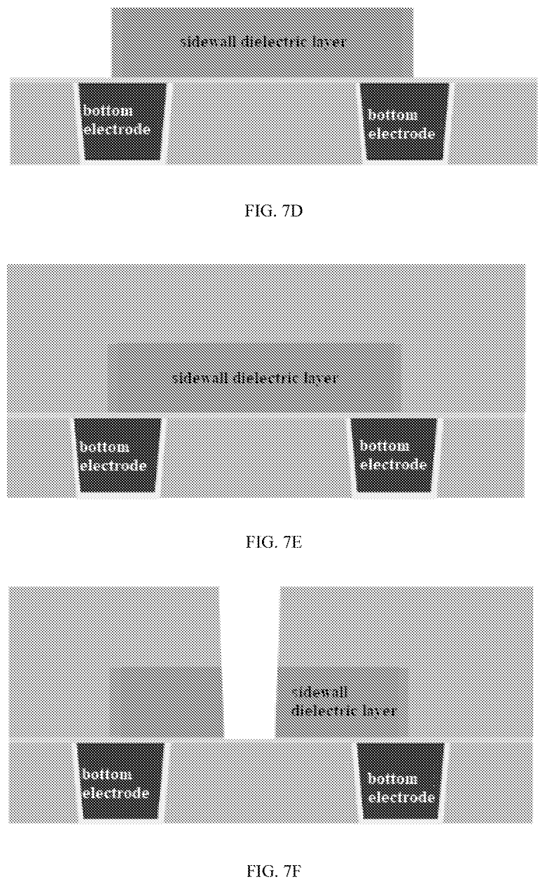

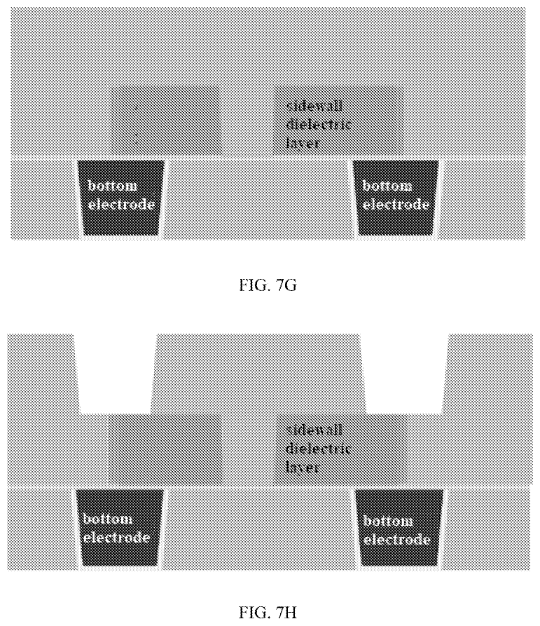

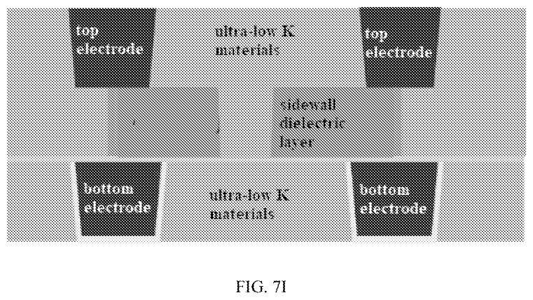

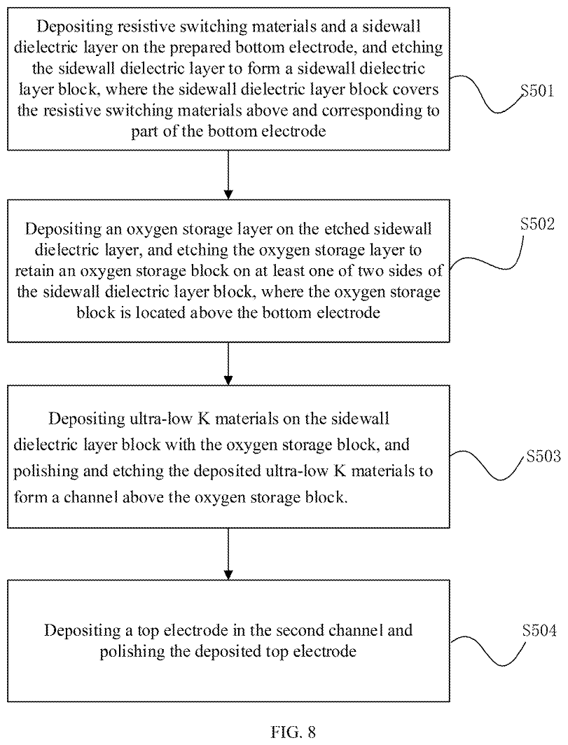

In some embodiments, as shown in FIGS. 6 and 7, optimizing the oxygen storage layer using the sidewall process includes:

At S401, resistive switching materials and a sidewall dielectric layer are deposited on the prepared bottom electrode successively, and the sidewall dielectric layer is etched to form a sidewall dielectric layer block, where the sidewall dielectric layer block covers the resistive switching materials above and corresponding to part of the bottom electrode.

That is, firstly, as shown in FIG. 7A, resistive switching materials and a sidewall dielectric layer are successively deposited on the prepared bottom electrode, and then, as shown in FIG. 7B, the sidewall dielectric layer is etched through an etching process, so as to form a sidewall dielectric layer block, where the sidewall dielectric layer block covers the resistive switching materials corresponding to part of the bottom electrode.

At S402, an oxygen storage layer is deposited on the etched sidewall dielectric layer, and the oxygen storage layer is etched to retain an oxygen storage block on at least one of two sides of the sidewall dielectric layer block, wherein the oxygen storage block is located above the bottom electrode.

That is, as shown in FIG. 7C, an oxygen storage layer is deposited on the etched sidewall dielectric layer, and the oxygen storage layer is etched through an etching process, so that an oxygen storage block is retained on at least one of two sides of the sidewall dielectric layer block (as shown in FIG. 7D); where the oxygen storage block is located above the bottom electrode.

At S403, ultra-low K materials are deposited on the sidewall dielectric layer block with the oxygen storage block, and then polished and etched to form a first channel on the sidewall dielectric layer block, where the first channel is staggered from the location of the bottom electrode.

That is, as shown in FIG. 7E, the ultra-low K materials are deposited on the sidewall dielectric layer block with the oxygen storage block, and then polished; as shown in FIG. 7F, the obtained element is then etched, so that the first channel is formed on the sidewall dielectric layer block, where the first channel is staggered from the position of the bottom electrode, so that the sidewall dielectric layer block is broken through the first channel to prevent the finally obtained resistive switching element from short circuiting.

At S404, ultra-low K materials are deposited corresponding to the first channel, and then polished and etched to form a second channel above the oxygen storage block.

That is, as shown in FIG. 7G, the ultra-low K materials are deposited corresponding to the first channel; then, as shown in FIG. 7H, the element is etched to form the second channel, and the second channel is located above the oxygen storage block.

At S405, a top electrode is deposited in the second channel and then polished.

That is, as shown in FIG. 7I, the top electrode is deposited in the second channel and the deposited top electrode is polished to complete the manufacture of the resistive switching element.

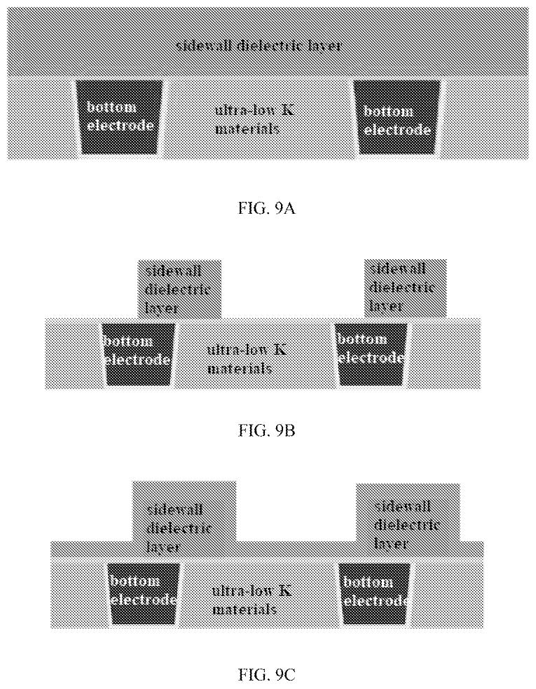

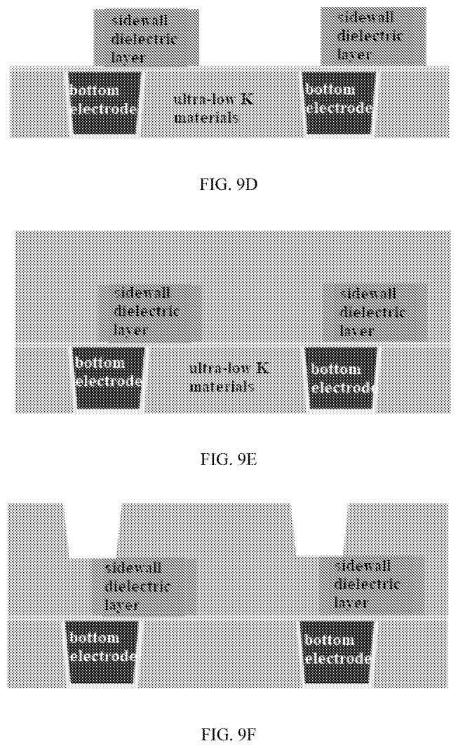

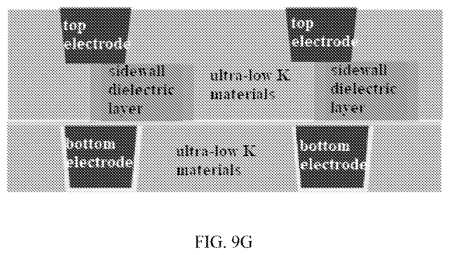

In some embodiments, as shown in FIG. 8 and FIGS. 9A-9G, optimizing the oxygen storage layer using the sidewall process includes:

At S501, resistive switching materials and a sidewall dielectric layer are deposited on the prepared bottom electrode successively, and the sidewall dielectric layer is etched to form a sidewall dielectric layer block, where the sidewall dielectric layer block covers the resistive switching materials above and corresponding to part of the bottom electrode.

That is, firstly, as shown in FIG. 9A, resistive switching materials and a sidewall dielectric layer are successively deposited on the prepared bottom electrode, and then, as shown in FIG. 9B, the sidewall dielectric layer is etched, so as to form a sidewall dielectric layer block, where the sidewall dielectric layer block covers the resistive switching materials above and corresponding to part of the bottom electrode.

At S502, an oxygen storage layer is deposited on the etched sidewall dielectric layer, and the oxygen storage layer is then etched to retain an oxygen storage block on at least one of two sides of the sidewall dielectric layer block, where the oxygen storage block is located above the bottom electrode.

That is, as shown in FIG. 9C, an oxygen storage layer is deposited on the etched sidewall dielectric layer, and then, as shown in FIG. 9D, the oxygen storage layer is etched, so that an oxygen storage block is retained on at least one of two sides of the sidewall dielectric layer block; where the oxygen storage block is located above the bottom electrode.

At S503, ultra-low K materials are deposited on the sidewall dielectric layer block with the oxygen storage block, and polished and etched to form a channel above the oxygen storage block.

That is, as shown in FIG. 9E, the ultra-low K materials are deposited on the sidewall dielectric layer block with the oxygen storage block, and then polished; as shown in FIG. 9F, the element is then etched, so that the channel is formed above the oxygen storage block.

At S504, a top electrode is deposited in the second channel and then polished.

That is, as shown in FIG. 9G, the top electrode is deposited in the channel and then the deposited top electrode is polished to complete the preparation of the resistive switching element.

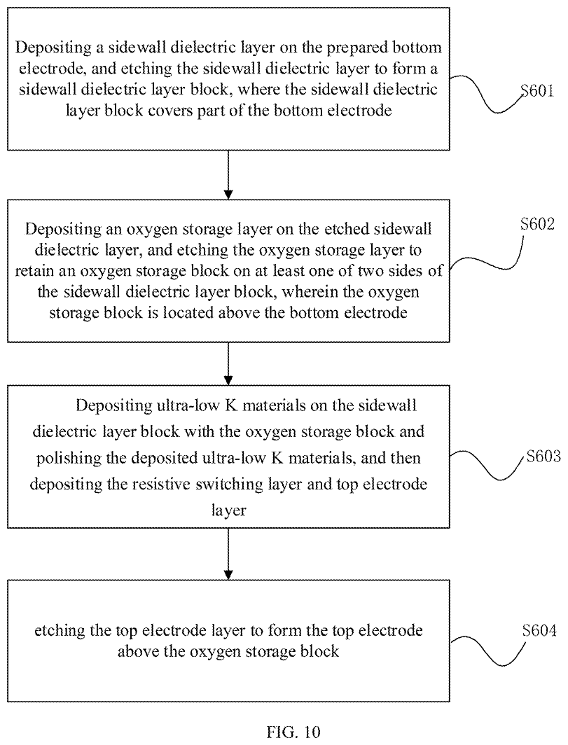

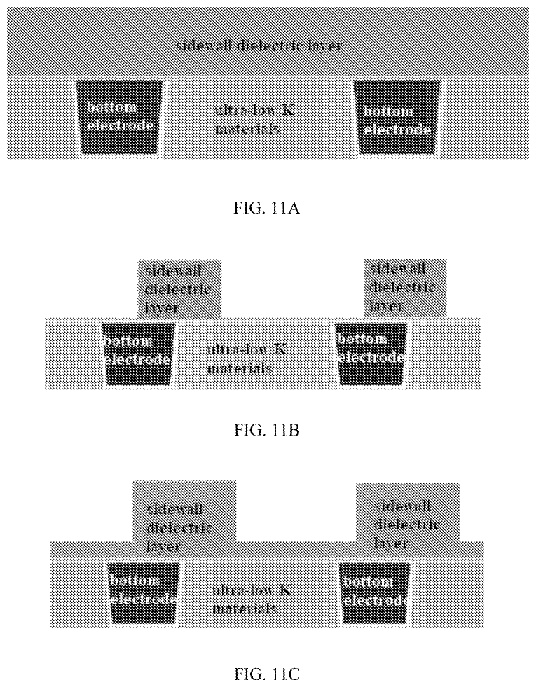

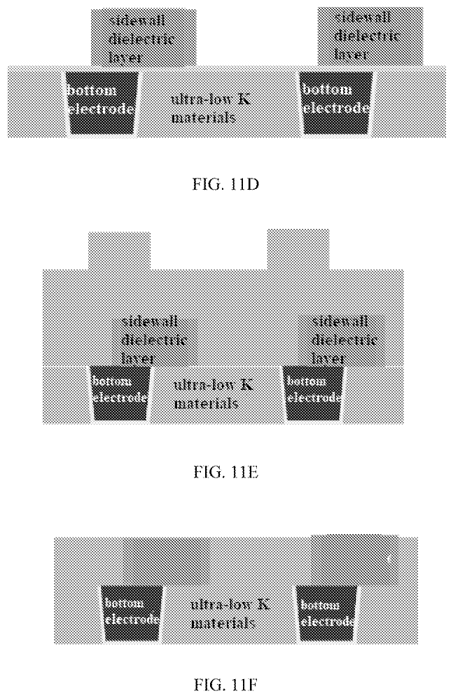

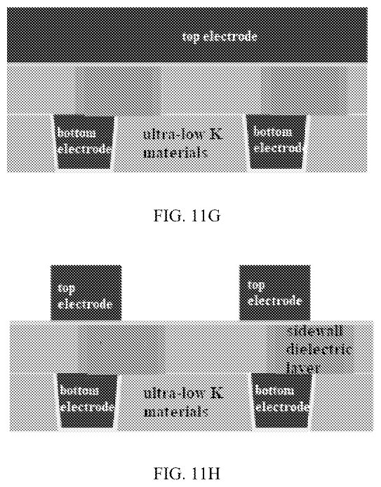

In some embodiments, as shown in FIG. 10 and FIGS. 11A-11H, optimizing the oxygen storage layer using the sidewall process includes:

At S601, a sidewall dielectric layer is deposited on the prepared bottom electrode, and the sidewall dielectric layer is etched to form a sidewall dielectric layer block, where the sidewall dielectric layer block covers part of the bottom electrode.

That is, firstly, as shown in FIG. 11A, a sidewall dielectric layer is deposited on the prepared bottom electrode, and then, as shown in FIG. 11B, the sidewall dielectric layer is etched, so as to form a sidewall dielectric layer block, where the sidewall dielectric layer block covers part of the bottom electrode.

At S602, an oxygen storage layer is deposited on the etched sidewall dielectric layer, and the oxygen storage layer is etched to retain an oxygen storage block on at least one of two sides of the sidewall dielectric layer block, wherein the oxygen storage block is located above the bottom electrode.

That is, as shown in FIG. 11C, an oxygen storage layer is deposited on the etched sidewall dielectric layer, and then, the oxygen storage layer is etched as shown in FIG. 11D, so that an oxygen storage block is retained on at least one of two sides of the sidewall dielectric layer block; where the oxygen storage block is located above the bottom electrode.

At S603, ultra-low K materials are deposited on the sidewall dielectric layer block with the oxygen storage block and polished, and then the resistive switching layer and top electrode layer are deposited.

That is, as shown in FIG. 11E, the ultra-low K materials are deposited on the sidewall dielectric layer block with the oxygen storage block, and the element is then polished by using the polishing process as shown in FIG. 11F; then, the resistive switching materials and the top electrode layer are deposited through the deposition process.

At S604, the top electrode layer is etched to form the top electrode above the oxygen storage block.

That is, as shown in FIG. 11H, the top electrode layer is etched to form the top electrode above the oxygen storage block.

In some embodiments, optimizing the bottom electrode by using the sidewall process includes: depositing a sidewall dielectric layer on a substrate of ultra-low K materials with a through hole, and etching the sidewall dielectric layer to form a sidewall dielectric layer block, wherein the sidewall dielectric layer block covers part of the through hole; and depositing a bottom electrode layer on the etched sidewall dielectric layer, and etching the bottom electrode layer to retain a bottom electrode on at least one of two sides of the sidewall dielectric layer block, wherein the bottom electrode is located above the through hole.

In some embodiments, after the bottom electrode is prepared, the method further comprises: depositing ultra-low K materials on the sidewall dielectric layer block with the bottom electrode, polishing and etching the deposited ultra-low K materials to form a first channel on the sidewall dielectric layer block, wherein the first channel is staggered from the location of the through hole; depositing ultra-low K materials in the first channel and polishing the deposited ultra-low K materials, and then depositing the resistive switching materials, the oxygen storage layer and a top electrode layer successively; etching the oxygen storage layer and the top electrode layer to form an oxygen storage block and the top electrode above the bottom electrode; depositing ultra-low K materials on the etched oxygen storage layer and top electrode layer, and polishing and etching the deposited ultra-low K materials to form a second channel above the top electrode; and depositing interconnection metal in the second channel and polishing the deposited interconnection metal.

In some embodiments, after the bottom electrode is prepared, the method further comprises: depositing ultra-low K materials on the sidewall dielectric layer block with the bottom electrode, and polishing the deposited ultra-low K materials; successively depositing the resistive switching materials, the oxygen storage layer and a top electrode layer; etching the oxygen storage layer and the top electrode layer to form an oxygen storage blocks and a top electrode above the bottom electrode; depositing ultra-low K materials on the etched oxygen storage layer and top electrode layer, and polishing and etching he deposited ultra-low K materials to form a channel above the top electrode; and depositing interconnection metal in the channel and polishing the deposited interconnection metal.

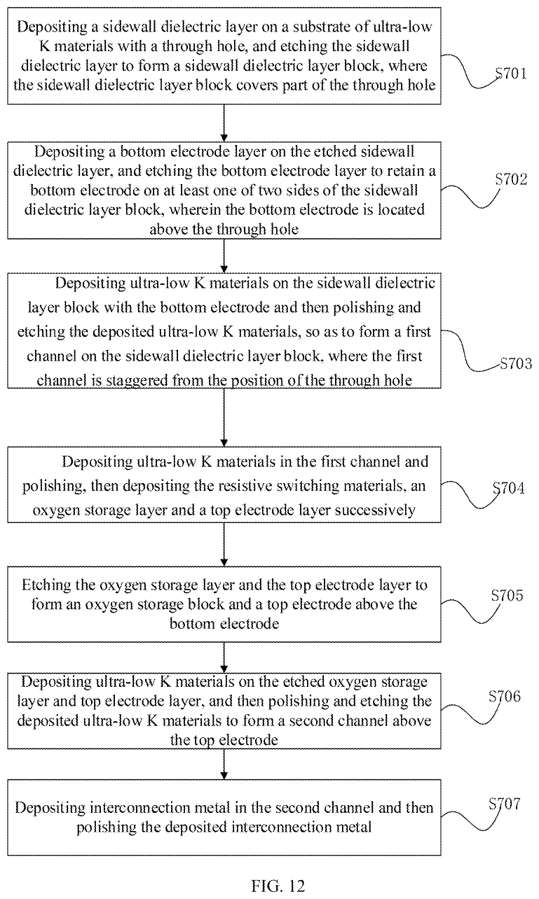

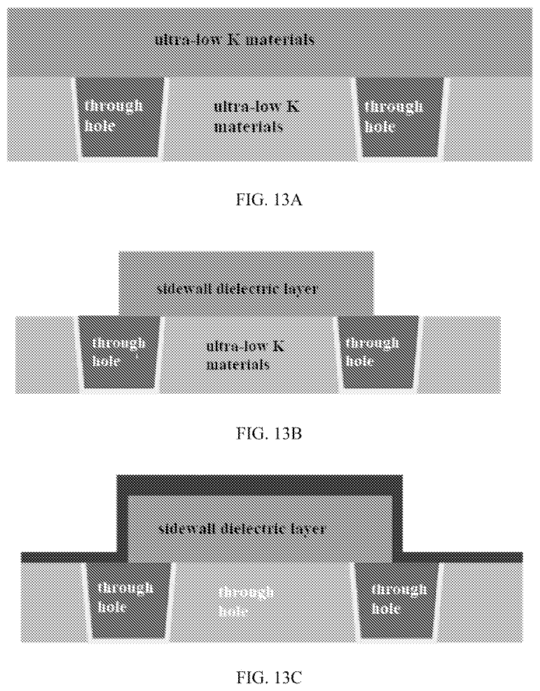

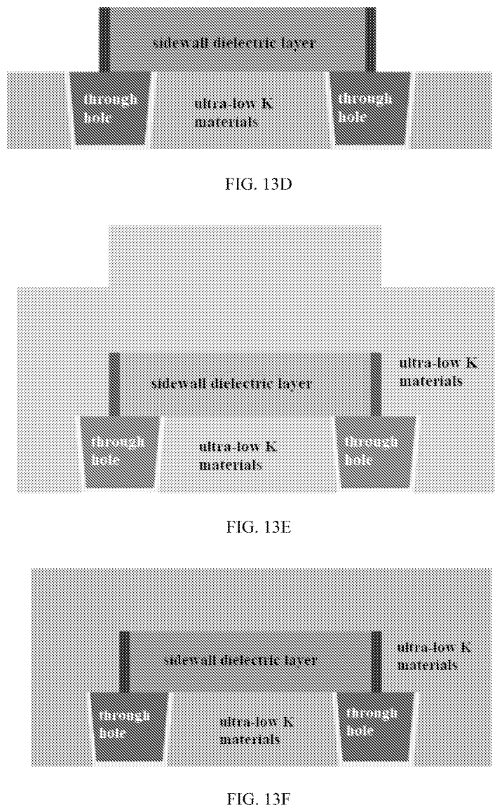

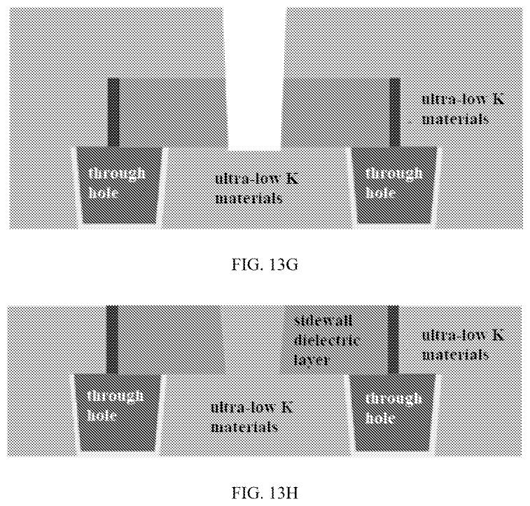

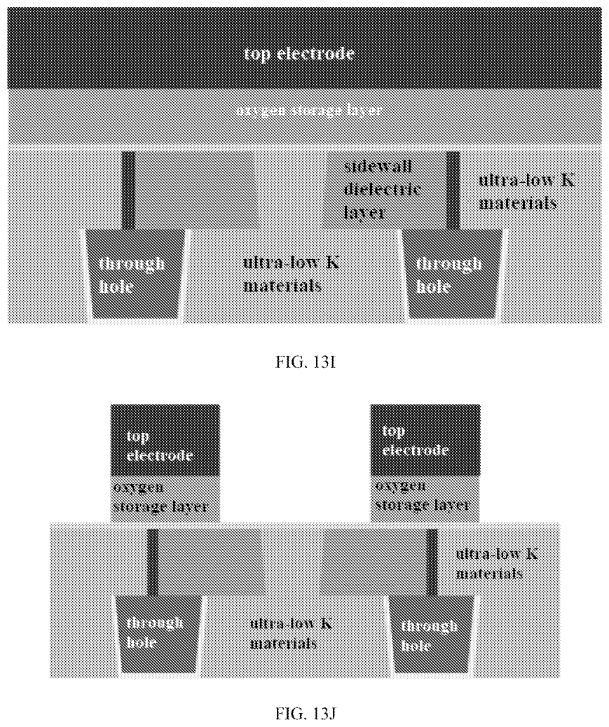

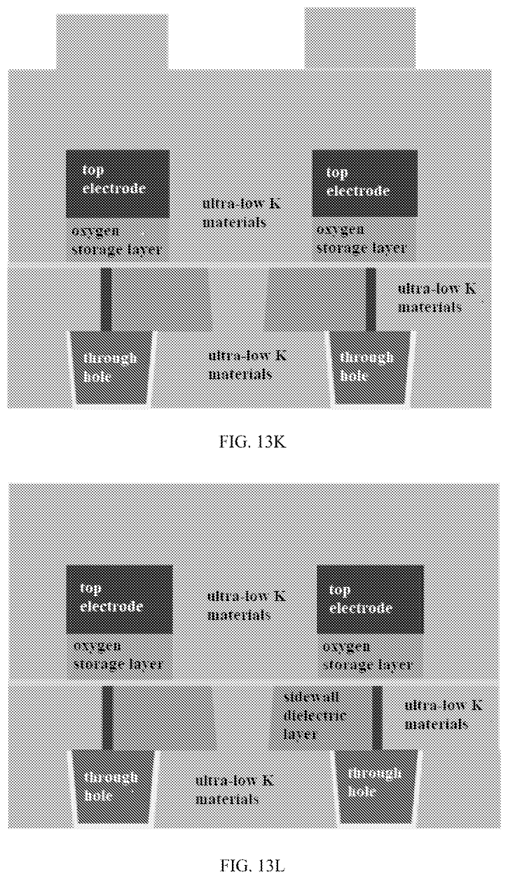

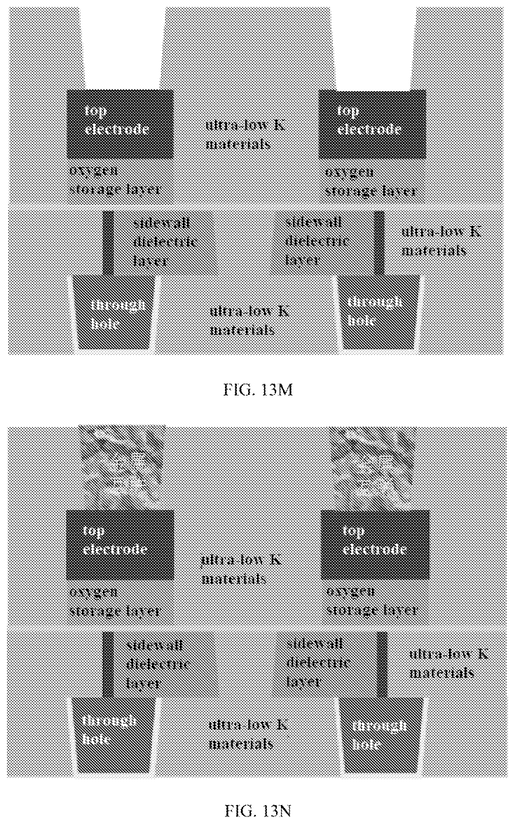

As an example, in a specific embodiment of the present invention, as shown in FIG. 12 and FIGS. 13A-13N, the method for manufacturing the resistive switching element includes steps of:

At S701, a sidewall dielectric layer is deposited on a substrate of ultra-low K materials with a through hole, and the sidewall dielectric layer is etched to form a sidewall dielectric layer block, where the sidewall dielectric layer block covers part of the through hole.

That is, firstly, as shown in FIG. 13A, a sidewall dielectric layer is deposited on a substrate of the ultra-low K materials with a through hole; then, an etching process is used to etch the sidewall dielectric layer as shown in FIG. 13B, so as to form a sidewall dielectric layer block, wherein the sidewall dielectric layer block covers part of the through hole.

At S702, a bottom electrode layer is deposited on the etched sidewall dielectric layer, and the bottom electrode layer is etched to retain a bottom electrode on at least one of two sides of the sidewall dielectric layer block, wherein the bottom electrode is located above the through hole.

That is, firstly, as shown in FIG. 13C, a bottom electrode layer is deposited on the etched sidewall dielectric layer; then, the bottom electrode layer is etched using an etching process as shown in FIG. 13D, so as to retain a bottom electrode on at least one of two sides of the sidewall dielectric layer block, wherein the bottom electrode is located above the through hole.

At S703, ultra-low K materials are deposited on the sidewall dielectric layer block with the bottom electrode and then polished and etched, so as to form a first channel on the sidewall dielectric layer block, where the first channel is staggered from the position of the through hole.

That is, firstly, as shown in FIG. 13E, the ultra-low-K materials are deposited on the sidewall dielectric layer block with the bottom electrode; then, the ultra-low-K materials are polished as shown in FIG. 13F through the polishing process, and etched as shown in FIG. 13G, so as to form a first channel on the sidewall dielectric layer block, where the first channel is staggered from the position of the through hole, so that the sidewall dielectric layer block is broken by the first channel to prevent the final resistive switching element from short circuit.

At S704, ultra-low K materials are deposited in the first channel and polished, then the resistive switching materials, an oxygen storage layer and a top electrode layer are deposited successively.

That is, as shown in FIG. 13H, the ultra-low K materials is deposited in the first channel and polished; then, as shown in FIG. 13I, resistive switching materials, an oxygen storage layer and a top electrode layer are successively deposited.

At S705, the oxygen storage layer and the top electrode layer are etched to form an oxygen storage block and a top electrode above the bottom electrode.

That is, as shown in FIG. 13J, the oxygen storage layer and the top electrode layer are etched by using an etching process to form an oxygen storage block and a top electrode above the bottom electrode.

At S706, ultra-low K materials are deposited on the etched oxygen storage layer and top electrode layer, and then are polished and etched to form a second channel above the top electrode.

That is, as shown in FIG. 13K, ultra-low-K materials are deposited on the etched oxygen storage layer and top electrode layer, and the ultra-low-K materials are polished through a polishing process as shown in FIG. 13L, and etched through an etching process as shown in FIG. 13M, so as to form a second channel above the top electrode.

At S707, interconnection metal is deposited in the second channel and then polished.

That is, as shown in FIG. 13N, the interconnection metal is deposited in the second channel and then polished, so as to complete the manufacture of the resistive switching element.

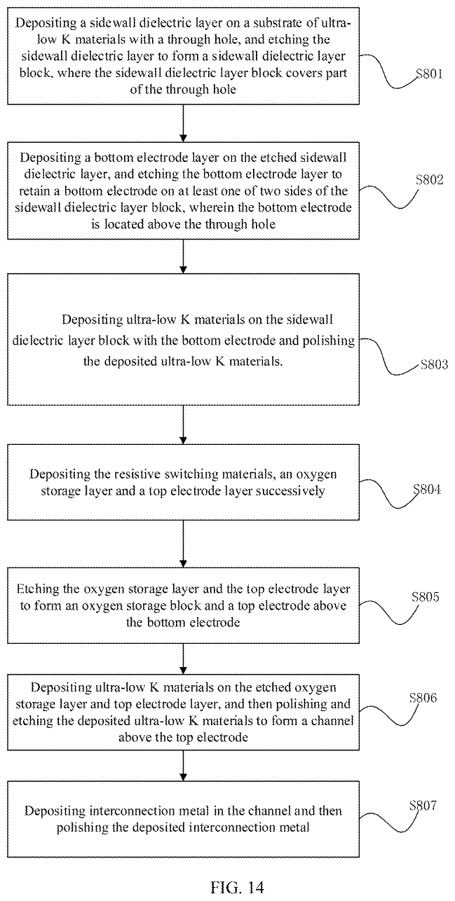

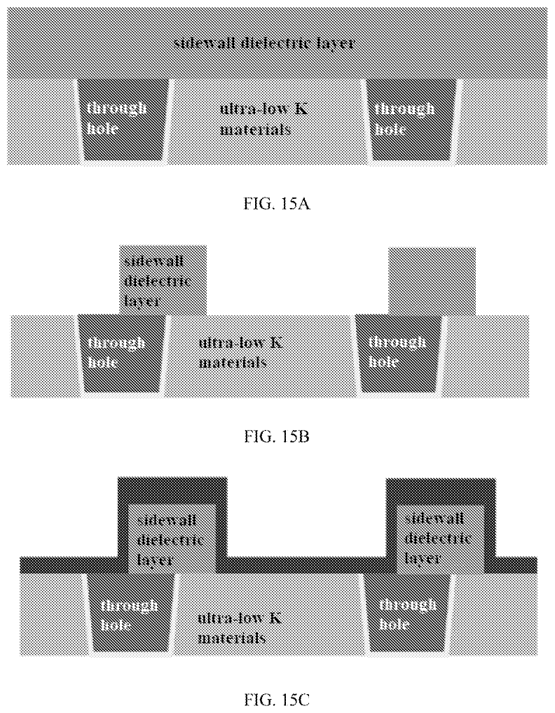

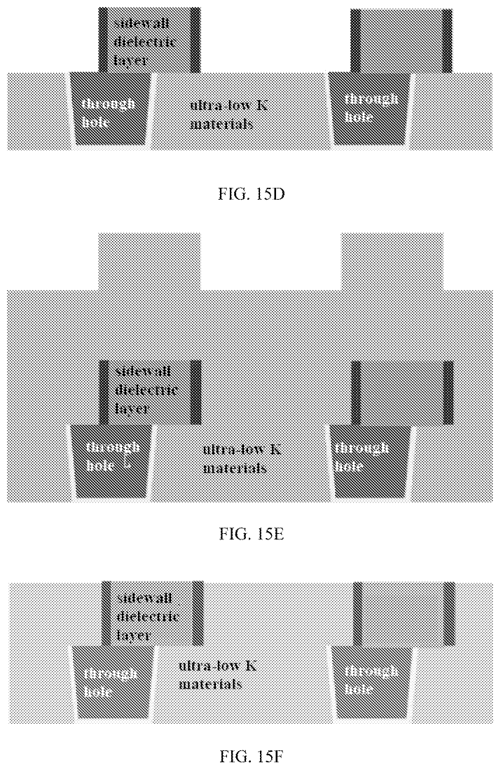

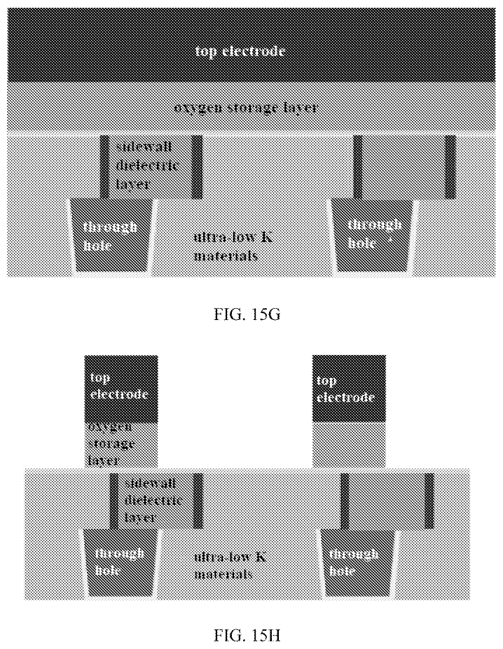

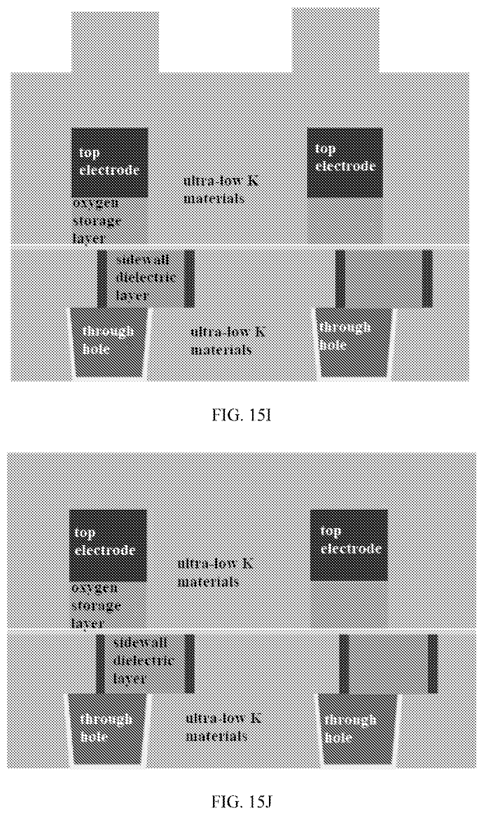

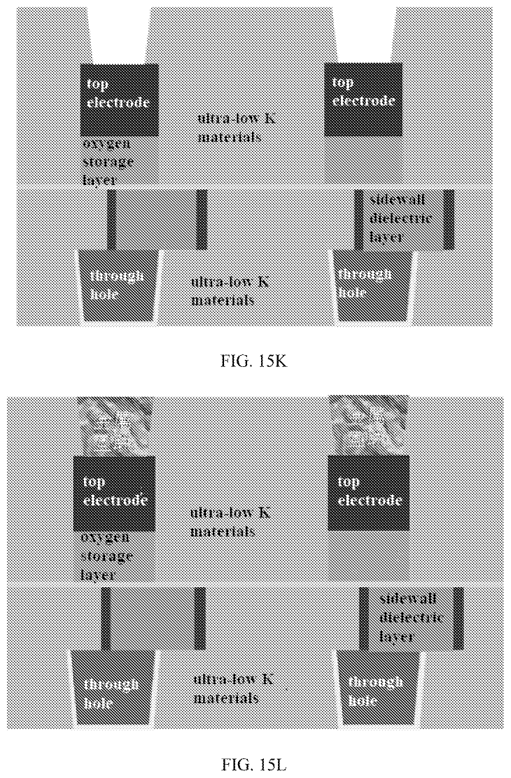

As another example, in a specific embodiment of the present invention, as shown in FIG. 14 and FIGS. 15A-15L, the method for manufacturing the resistive switching element includes steps of:

At S801, a sidewall dielectric layer is deposited on a substrate of ultra-low K materials with a through hole, and the sidewall dielectric layer is etched to form a sidewall dielectric layer block, where the sidewall dielectric layer block covers part of the through hole.

That is, firstly, as shown in FIG. 15A, a sidewall dielectric layer is deposited on a substrate of the ultra-low K materials with a through hole; then, the sidewall dielectric layer is etched as shown in FIG. 15B, so as to form a sidewall dielectric layer block, wherein the sidewall dielectric layer block covers part of the through hole.

At S802, a bottom electrode layer is deposited on the etched sidewall dielectric layer, and the bottom electrode layer is etched to retain a bottom electrode on at least one of two sides of the sidewall dielectric layer block, wherein the bottom electrode is located above the through hole.

That is, as shown in FIG. 15C, a bottom electrode layer is deposited on the etched sidewall dielectric layer; then, the bottom electrode layer is etched as shown in FIG. 15D, so as to retain a bottom electrode on at least one of two sides of the sidewall dielectric layer block, wherein the bottom electrode is located above the through hole.

At S803, ultra-low K materials are deposited on the sidewall dielectric layer block with the bottom electrode and polished.

That is, as shown in FIG. 15E, the ultra-low-K materials are deposited on the sidewall dielectric layer block with the bottom electrode, and then polished as shown in FIG. 15F through the polishing process.

At S804, the resistive switching materials, an oxygen storage layer and a top electrode layer are deposited successively.

That is, as shown in FIG. 15G, resistive switching materials, an oxygen storage layer and a top electrode layer are successively deposited.

At S805, the oxygen storage layer and the top electrode layer are etched to form an oxygen storage block and a top electrode above the bottom electrode.

That is, as shown in FIG. 15H, the oxygen storage layer and the top electrode layer are etched to form an oxygen storage block and a top electrode above the bottom electrode.

At S806, ultra-low K materials are deposited on the etched oxygen storage layer and top electrode layer, and then are polished and etched to form a channel above the top electrode.

That is, as shown in FIG. 15I, ultra-low-K materials are deposited on the etched oxygen storage layer and top electrode layer, polished through a polishing process as shown in FIG. 15J, and etched through an etching process as shown in FIG. 15K, so as to form a channel above the top electrode.

At S807, interconnection metal is deposited in the channel and then polished.

That is, as shown in FIG. 15L, the interconnection metal is deposited in the channel and then polished.

The method for manufacturing a resistive switching element according to the present invention is provided, where the resistive switching element includes a bottom electrode, a top electrode and a resistive switching layer disposed between the bottom electrode and the top electrode, the resistive switching layer includes an oxygen storage layer adjacent to the top electrode and resistive switching materials adjacent to the bottom electrode, the method includes steps of: performing an etching process, a deposition process and a polishing process alternately to prepare the bottom electrode, the resistive switching layer and the top electrode; optimizing at least one of the bottom electrode, the resistive switching materials and the oxygen storage layer by using the sidewall process when preparing the bottom electrode and the resistive switching materials, so as to reduce a contact area between the bottom electrode and the resistive switching materials, and/or reduce a contact area between the resistive switching materials and the oxygen storage layer, by using optimization process. Therefore, the contacting area between components of the resistive switching element is reduced, conductive filaments are gathered in a small effective area, and thus the electrical properties of the resistive switching element can be greatly improved.

In order to achieve the above objects, an embodiment according to the present invention provides a resistive switching element manufactured according to the method as described above.

In the resistive switching element according to the embodiments of the present invention, the contacting area between components of the resistive switching element is reduced, conductive filaments are gathered in a small effective area, and thus the electrical properties of the resistive switching element can be greatly improved.

In order to achieve the above objects, an embodiment according to another aspect of the present invention provides a resistive switching memory including a plurality of resistive switching elements as described above, and, the plurality of resistive switching elements is arranged in an array.

In the resistive switching memory according to the embodiments of the present invention, the contacting area between components of the resistive switching elements in the resistive switching memory is reduced, conductive filaments are gathered in a small effective area, and thus the electrical properties of the resistive switching element can be greatly improved. Besides, the resistive switching elements in are arranged in an array, which greatly improving the electric properties of the entire resistive switching memory.

As will be appreciated by those skilled in the art, embodiments of the present invention may be provided as a method, system, or computer program product. Accordingly, the present invention may be embodied as an entirely hardware embodiment, an entirely software embodiment, or an embodiment combining software and hardware. Furthermore, the present invention may be embodied as a computer program product performed on one or more computer-usable storage media (including, but not limited to, disk storage, CD-ROM, optical storage, etc.) having computer-usable program code embodied therein.

The present invention is described with reference to flowchart and/or block diagrams illustrating methods, apparatus (systems), and computer program products according to embodiments of the invention. It will be understood that each step and/or block in the flowcharts and/or block diagrams, and combinations of steps and/or blocks in the flowcharts and/or block diagrams can be implemented by computer program instructions. These computer program instructions may be provided to the processor of a general computer, specific computer, embedded processor or other programmable data processing devices to produce a machine such that means for implementing the functions specified in one or more steps of the flowcharts and/or one or more blocks of the block diagrams may be the produced by instructions executed by the processor of the computer or other programmable data processing device.

These computer program instructions may also be stored in a computer-readable memory capable of directing a computer or other programmable data processing devices to function in a particular manner, such that the instructions stored in the computer-readable memory produce apparatus including instruction device. The instruction device implements the functions specified in a step or steps of the flowcharts and/or a block or blocks of the block diagrams.

These computer program instructions can also be loaded on a computer or other programmable data processing device, so as to cause a series of operational steps to be performed on the computer or other programmable device to produce a computer-implemented process such that the instructions provide steps for implementing the functions specified in one or more steps of the flowcharts and/or one or more blocks of the block diagrams.

It should be noted that, in the claims, any reference signs placed between parentheses shall not be construed as limiting the claim. The word “comprising” does not exclude the presence of elements or steps not listed in a claim. The word “a” or “an” preceding an element does not preclude the presence of a plurality of such elements. The invention can be implemented by means of hardware comprising several different components and by means of a computer suitably programmed. In a product claim enumerating several devices, some of these devices may be embodied by one hardware. The use of the words “first”, “second”, and “third” etc. do not denote any order. These words can be interpreted as names.

Although preferred embodiments of the present invention have been described, additional changes and modifications to these embodiments may be made by those skilled in the art once the basic inventive concepts are known. Therefore, the appended claims are intended to be construed to include the preferred embodiment and all changes and modifications that fall within the scope of the present invention.

It will be apparent to those skilled in the art that various modifications and variations can be made to the present invention without departing from the spirit and scope of the invention. Thus, provided that these modifications and variations of the present invention fall within the scope of the claims of the present invention and their equivalents, these modifications and variations are also intended to be included in the present invention.

In the description of the present invention, it should be understood that the terms “first” and “second” are only used for description, and cannot be interpreted as indicating or implying relative importance or implying the number of indicated technical features. Thus, a feature defined as “first” or “second” may expressly or implicitly include one or more of these features. In the description of the present invention, “plurality” means two or more, unless otherwise expressly and specifically defined.

In the present invention, unless otherwise expressly specified and limited, the terms “installed”, “connection”, “connected”, “fixed” and other terms should be understood in a broad sense, for example, it may be a fixed connection or a detachable connection , or integrated connection; it may be a mechanical connection or an electrical connection; it may be a direct connection or an indirect connection through an intermediate medium, and it can be the internal connection of the two elements or the interaction relationship between the two elements. For those skilled in the art, the specific meanings of the above terms in the present invention can be understood according to specific situations.

In the present invention, unless otherwise expressly specified and limited, a first feature being “above” or “under” a second feature may refer to that the first feature directly contacts the second feature, or the first feature indirectly contacts the second feature through an intermediary medium. Also, the first feature being “above”, “over” and “on” the second feature may refer to that the first feature is directly above or obliquely above the second feature, or simply means that the first feature is disposed higher than the second feature. The first feature being “below”, “under” the second feature may refer to that the first feature is directly below or obliquely below the second feature, or simply refers to that the first feature is disposed lower than the second feature.

In the description of this specification, description of “one embodiment,” “some embodiments,” “example,” “specific example,” or “some examples”, etc., refers to specific features structure, material or characteristics described in connection with the embodiment or example are included in at least one embodiment or example of the present invention. In this specification, schematic representations for the above terms should not be construed as necessarily referring to the same embodiment or example. Furthermore, the particular features, structures, materials or characteristics described may be combined in any suitable manner in any one or more embodiments or examples. Furthermore, if not conflicting with each other, those skilled in the art may combine different embodiments or examples described in this specification, as well as the features of the different embodiments or examples.

Although the embodiments of the present invention have been illustrated and described above, it should be understood that the above-mentioned embodiments are exemplary and should not be construed as limiting the present invention. Variations, modifications, substitutions, and alterations to the above-described embodiments can be made by those of ordinary skill in the art within the scope of the present invention.

1. A method for manufacturing a resistive switching element, wherein the resistive switching element comprises a bottom electrode, a top electrode and a resistive switching layer disposed between the bottom electrode and the top electrode, the resistive switching layer comprising an oxygen storage layer adjacent to the top electrode and resistive switching materials adjacent to the bottom electrode, the method comprising steps of:
performing an etching process, a deposition process and a polishing process alternately to prepare the bottom electrode, the resistive switching layer and the top electrode;
optimizing at least one of the bottom electrode, the resistive switching materials and the oxygen storage layer by using the sidewall process when preparing the bottom electrode and the resistive switching materials, so as to reduce a contact area between the bottom electrode and the resistive switching materials, and/or reduce a contact area between the resistive switching materials and the oxygen storage layer.

2. The method for manufacturing a resistive switching element according to claim 1, wherein optimizing the resistive switching materials by using the sidewall process comprising:
depositing a first protective dielectric layer on the prepared bottom electrode, and etching the first protective dielectric layer to form a trench above the bottom electrode, wherein the trench covers part of the bottom electrode; and
successively depositing resistive switching materials and a second protective dielectric layer on the first protective dielectric layer with the trench, and polishing the second protective dielectric layer.

3. The method for manufacturing a resistive switching element according to claim 1, wherein optimizing the resistive switching materials by using the sidewall process comprising:
depositing a first protective dielectric layer on the prepared bottom electrode, and etching the first protective dielectric layer to form a protective dielectric block above the bottom electrode, wherein the protective dielectric block covers part of the bottom electrode; and
successively depositing resistive switching materials and a second protective dielectric layer on the bottom electrode with the protective dielectric block, and polishing the second protective dielectric layer.

4. The method for manufacturing a resistive switching element according to claim 2, wherein, the method further comprises the following steps after polishing the second protective dielectric layer:
successively depositing the oxygen storage layer and a top electrode layer above the polished second protective dielectric layer, and etching the deposited oxygen storage layer and top electrode layer to form an oxygen storage layer and a top electrode above and corresponding to the bottom electrode;
depositing ultra-low K materials, and polishing and etching the etched ultra-low K materials to form a channel corresponding to a position of the top electrode; and
depositing interconnection metal in the channel and polishing the deposited interconnection metal.

5. The method for manufacturing a resistive switching element according to claim 1, wherein optimizing the oxygen storage layer by using the sidewall process comprising:
successively depositing resistive switching materials and a sidewall dielectric layer on the prepared bottom electrode, and etching the sidewall dielectric layer to form a sidewall dielectric layer block, wherein the sidewall dielectric layer block covers the resistive switching materials above and corresponding to part of the bottom electrode;
depositing the oxygen storage layer on the etched sidewall dielectric layer, and etching the oxygen storage layer to retain an oxygen storage block on at least one of two sides of the sidewall dielectric layer block, wherein the oxygen storage block is located above the bottom electrode;
depositing ultra-low K materials on the sidewall dielectric layer block with the oxygen storage block, and polishing and etching the deposited ultra-low K materials to form a first channel on the sidewall dielectric layer block, wherein the first channel is staggered from bottom electrode;
depositing ultra-low K materials in the first channel, and polishing and etching the deposited ultra-low K materials to form a second channel above the oxygen storage block; and
depositing the top electrode in the second channel and polishing the deposited top electrode.

6. The method for manufacturing a resistive switching element according to claim 1, wherein optimizing the oxygen storage layer by using the sidewall process comprising:
successively depositing resistive switching materials and a sidewall dielectric layer on the prepared bottom electrode, and etching the sidewall dielectric layer to form a sidewall dielectric layer block, wherein the sidewall dielectric layer block covers the resistive switching materials above and corresponding to part of the bottom electrode;
depositing the oxygen storage layer on the etched sidewall dielectric layer, and etching the oxygen storage layer to retain am oxygen storage block on at least one of two sides of the sidewall dielectric layer block, wherein the oxygen storage block is located above the bottom electrode;
depositing ultra-low K materials on the sidewall dielectric layer block with the oxygen storage block, and polishing and etching the deposited ultra-low K materials to form a channel on the oxygen storage block; and
depositing the top electrode in the channel and polishing the deposited top electrode.

7. The method for manufacturing a resistive switching element according to claim 1, wherein optimizing the oxygen storage layer by using the sidewall process comprising:
depositing a sidewall dielectric layer on the prepared bottom electrode, and etching the sidewall dielectric layer to form a sidewall dielectric layer block, wherein the sidewall dielectric layer block covers part of the bottom electrode;
depositing the oxygen storage layer on the etched sidewall dielectric layer, and etching the oxygen storage layer to retain an oxygen storage block on at least one of two sides of the sidewall dielectric layer block, wherein the oxygen storage block is located above the bottom electrode;
depositing ultra-low K materials on the sidewall dielectric layer block with the oxygen storage block and polishing the deposited ultra-low K materials, and depositing the resistive switching materials and a top electrode layer; and
etching the top electrode layer to form the top electrode on the oxygen storage block.

8. The method for manufacturing a resistive switching element according to claim 1, wherein optimizing the bottom electrode by using the sidewall process comprising:
depositing a sidewall dielectric layer on a substrate of ultra-low K materials with a through hole, and etching the sidewall dielectric layer to form a sidewall dielectric layer block, wherein the sidewall dielectric layer block covers part of the through hole; and
depositing a bottom electrode layer on the etched sidewall dielectric layer, and etching the bottom electrode layer to retain a bottom electrode on at least one of two sides of the sidewall dielectric layer block, wherein the bottom electrode is located above the through hole.

9. The method for manufacturing a resistive switching element according to claim 8, wherein after the bottom electrode is prepared, the method further comprises:
depositing ultra-low K materials on the sidewall dielectric layer block with the bottom electrode, polishing and etching the deposited ultra-low K materials to form a first channel on the sidewall dielectric layer block, wherein the first channel is staggered from the location of the through hole;
depositing ultra-low K materials in the first channel and polishing the deposited ultra-low K materials, and then depositing the resistive switching materials, the oxygen storage layer and a top electrode layer successively;
etching the oxygen storage layer and the top electrode layer to form an oxygen storage block and the top electrode above the bottom electrode;
depositing ultra-low K materials on the etched oxygen storage layer and top electrode layer, and polishing and etching the deposited ultra-low K materials to form a second channel above the top electrode; and
depositing interconnection metal in the second channel and polishing the deposited interconnection metal.

10. The method for manufacturing a resistive switching element according to claim 8, wherein after the bottom electrode is prepared, the method further comprises:
depositing ultra-low K materials on the sidewall dielectric layer block with the bottom electrode, and polishing the deposited ultra-low K materials;
successively depositing the resistive switching materials, the oxygen storage layer and a top electrode layer;
etching the oxygen storage layer and the top electrode layer to form an oxygen storage blocks and a top electrode above the bottom electrode;
depositing ultra-low K materials on the etched oxygen storage layer and top electrode layer, and polishing and etching he deposited ultra-low K materials to form a channel above the top electrode; and
depositing interconnection metal in the channel and polishing the deposited interconnection metal.

11. A resistive switching element, wherein, the resistive switching element is manufactured by the method according to claim 1.

12. A resistive switching memory comprising a plurality of resistive switching elements according to claim 11, wherein, the plurality of resistive switching elements is arranged in an array.
